(19) United States
(12) Patent Application Publication
(10) Pub. No.: US 2018/0358468 A1
(43) Pub. Date: Dec. 13, 2018

(54) FABRICATION METHOD OF THIN FILM TRANSISTOR, ARRAY SUBSTRATE, AND LIQUID CRYSTAL DISPLAY PANEL

(71) Applicant: Shenzhen China Star Optoelectronics Semiconductor Display Technology Co., Ltd., Shenzhen, Guangdong (CN)

(72) Inventors: Chunsheng JIANG, Shenzhen, Guangdong (CN); Yue WU, Shenzhen, Guangdong (CN)

(73) Assignee: Shenzhen China Star Optoelectronics Semiconductor Display Technology Co., Ltd., Shenzhen, Guangdong (CN)

(21) Appl. No.: 15/739,706

(22) PCT Filed: Jul. 21, 2017
(86) PCT No.: PCT/CN2017/093846

§ 371 Date: Dec. 23, 2017

(30) Foreign Application Priority Data
Jun. 8, 2017 (CN) 201710428424.1

(51) Int. Cl. H01L 29/786; H01L 27/12; H01L 29/66; H01L 21/465; G02F 1/1368

(52) U.S. Cl. CPC H01L 29/7869; H01L 27/1225; H01L 27/1259; H01L 29/66969; G02F 2202/16; G02F 1/1368; H01L 29/78618; G02F 2001/13685; G02F 2202/10; H01L 21/465

(57) ABSTRACT

The present disclosure proposes a fabrication method of a thin film transistor, an array substrate, and a liquid crystal display panel. The fabrication method includes: forming a metallic oxide semiconductor layer on a substrate, forming a gate insulating layer on the channel of the metallic oxide semiconductor layer, and forming a gate on the gate insulating layer, and etching the source area and the drain area of the metallic oxide semiconductor layer with a metallic etching solution to transform the metallic oxide semiconductor layer at the source area and the drain area into a conductor, removing the metallic etching solution, and continuously depositing an interlayer insulating layer, a source, a drain, a passivation layer, and a pixel electrode successively. Because the metallic elements are removed from the metallic oxide semiconductor, the stability of the metallic oxide conductor and the performance of the TFT are enhanced.

### FIELD OF THE DISCLOSURE

The present disclosure relates to the field of semiconductor display, and more particularly, to a fabrication method of a thin film transistor (TFT), an array substrate, and a liquid crystal display (LCD) panel.

### DESCRIPTION OF THE RELATED ART

Each subpixel in a TFT needs to transform a subpixel at a high speed in a practical device with a high resolution and a high frame so the TFT should have the property of low parasitic capacitance and high electron mobility. An oxide semiconductor TFT with a higher electron mobility attracts an extensive attention. As far, the oxide semiconductor TFT primarily adopts a standard ESL structure and a standard BCE structure, which are both bottom gates. However, the TFT with the above-mentioned standard structure has relatively larger parasitic capacitance and is hard to become smaller, which are shortcomings. Therefore, the TFT with the above-mentioned standard structure is harder to be used in a large-sized or high-resolution display device. In other words, top-gate TFTs are very important for a large-sized or high-resolution display device.

The structure of the top-gate TFT is illustrated in FIG. 1. A block layer 12 is arranged on the surface of a glass substrate 11. An oxide semiconductor layer 13 is arranged on the block layer 12. A gate insulating layer 14 and a gate 15 are arranged on the oxide semiconductor layer 13. An inter-layer medium 16 covers the surface of the block layer 12, the surface of the oxide semiconductor layer 13, and the surface of the gate 15. Sources/drains 17 and 18 are arranged at both sides of the gate 15 and electrically connected to the oxide semiconductor layer 13. To lower the resistor of the sources/drains 17 and 18 touching a channel of the oxide semiconductor layer 13, the oxide semiconductor layer 13 between the sources/drains 17 and 18 and the gate 15 undergoes a conductivity process in the manufacturing process; that is a conductor is formed on the oxide semiconductor layer 13 between the sources/drains 17 and 18 and the gate 15.

Generally, the surface of an oxide semiconductor layer in the conductivity technique is processed with gases such as H₂, NH₃, CF₄, SF₆, He, Ar, and N₂, which usually result in impure gases like an H ion and an F ion due to the processing of the third-party gas. These ions are diffused to the oxide semiconductor layer in a subsequent process, which affects the property of the TFT. On the other hand, the use of noble gases may lead to an unexpected conductivity effect. The resistor of a source/drain touching a channel of the oxide semiconductor layer is still higher, which causes a problem like a lower on-state current.

### SUMMARY

An object of the present disclosure is to propose a fabrication method of a TFT, an array substrate, and an LCD panel. The stability of a metallic oxide conductor is enhanced with the adoption of the fabrication method.

According to the present disclosure, an array substrate includes a substrate and a plurality of thin film transistors (TFTs) arranged on the substrate. The TFT includes a block insulating layer arranged on the substrate and a metallic oxide semiconductor layer formed on the block insulating layer, The metallic oxide semiconductor layer includes a source area, a drain area, and a channel. The TFT also includes a gate insulating layer and a gate, both arranged on the channel of the metallic oxide semiconductor layer. The TFT also includes an interlayer insulating layer, a source, a drain, a passivation layer and a pixel electrode, all arranged on the metallic oxide semiconductor layer, the gate insulating layer, and the gate. The source is connected to the source area of the metallic oxide semiconductor layer. The drain is connected to the drain area of the metallic oxide semiconductor layer. The pixel electrode is connected to the drain. The source area and the drain area of the metallic oxide semiconductor layer are etched with a metallic etching solution.

The present disclosure brings benefits as follows. Compared with the related art, a metallic etching solution is adopted by the present disclosure providing a fabrication method of a TFT to process metallic oxide semiconductor. The metallic etching solution removes metallic elements which are inclined to be etched by the metallic etching solution, and the other metallic elements which are hard to be etched by the metallic etching solution are preserved. In other words, the metallic oxide semiconductor is transformed into a conductor. Since the metallic elements are removed from the metallic oxide semiconductor, an oxygen element in a silicon oxide at both sides of the metallic oxide semiconductor does not extend to the merely transformed conductor, thereby enhancing the stability of the metallic oxide conductor and the performance of the TFT.

### BRIEF DESCRIPTION OF THE DRAWINGS

FIG. 1 illustrates a structure of a conventional thin film transistor.

FIG. 2 illustrates a flowchart of a fabrication method of an array substrate according to an embodiment of the present disclosure.

FIG. 3 illustrates a flowchart of the block S101 as illustrated in FIG. 2 according to an embodiment of the present disclosure.

FIG. 4a through FIG. 4b are cross sectionbal views of the thin film transistor corresponding to blocks S101-S103 as illustrated in FIG. 2.

FIG. 5 illustrates a flowchart of the block S104 as illustrated in FIG. 2.

FIG. 6a through FIG. 6b are cross sectionbal views of the thin film transistor corresponding to blocks as illustrated in FIG. 5.

FIG. 7 illustrates a flowchart of the block S101 as illustrated in FIG. 2 according to another embodiment of the present disclosure.

FIG. 8 is a cross sectionbal view of the thin film transistor fabricated based on the flowchart of FIG. 7.

FIG. 9 illustrates an array substrate according to an embodiment of the present disclosure.

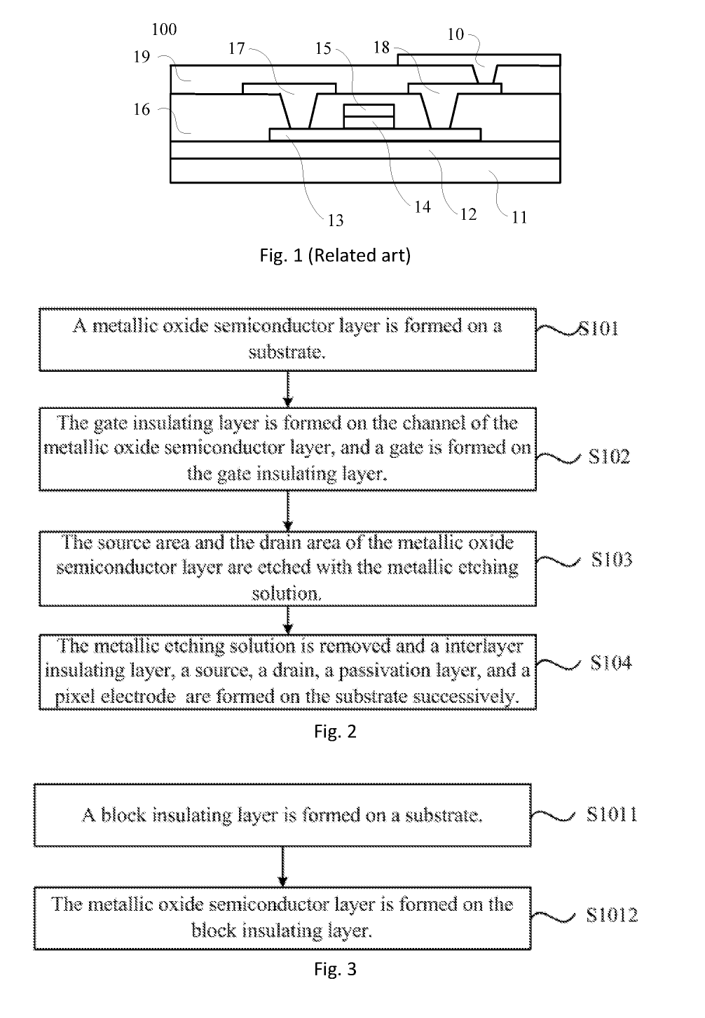

### DETAILED DESCRIPTION OF THE EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

Please refer to FIG. 2 illustrating a flowchart of a fabrication method of an array substrate according to an embodiment of the present disclosure. The fabrication method proposed by the embodiment includes block S101, block S102, block S103, and block S104, as FIG. 2 illustrates.

At block S101, a metallic oxide semiconductor layer 22 is formed on a substrate 20.

Specifically, the substrate 20 may be fabricated by polyethylene naphthalene (PEN), polyethylene terephthalate (PET), polyimide (PI) or glass.

The metallic oxide semiconductor layer 22 is formed on the substrate 20 with a method such as sputtering and chemical vapor deposition (CVD). The metallic oxide semiconductor layer 22 is patterned to form the patterned metallic oxide semiconductor layer 22. The metallic oxide semiconductor layer 22 is divided into a source area 221, a drain area 222, and a channel 223. The source area 221 and the drain area 222 are arranged at both sides of the channel 223 correspondingly.

Further, FIG. 3 may include block S1011 and block S1012.

At block S1011, a block insulating layer 21 is formed on a substrate 20.

A block insulating layer 21 is deposited on the substrate 20 with the method such as CVD to separate the metallic oxide semiconductor layer 22 from the substrate 20. In this way, the performance of the metallic oxide semiconductor is not affected by the substrate 20.

At block S1012, the metallic oxide semiconductor layer 22 is formed on the block insulating layer 21.

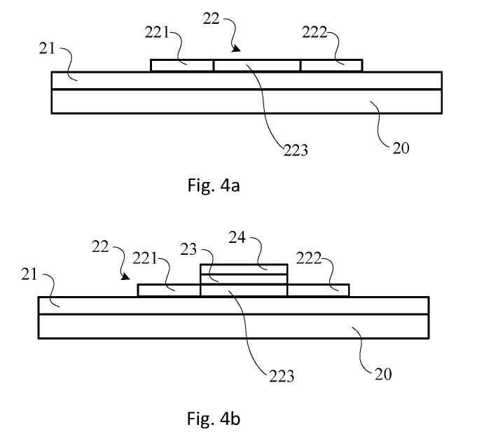

The metallic oxide semiconductor layer 22 is formed on the block insulating layer 21 with a method such as sputtering and CVD. The metallic oxide semiconductor layer 22 is patterned with a mask to form the patterned metallic oxide semiconductor layer 22. The metallic oxide semiconductor layer 22 may be an indium gallium zinc oxide (IGZO) semiconductor layer or other kinds of metallic oxide semiconductor material layers. It is notified that the semiconductor material of the metallic oxide semiconductor layer 22 needs to have properties of low charge carrier density and high electron mobility. In this embodiment, the metallic oxide semiconductor layer 22 is divided into the source area 221, the drain area 222, and the channel 223. The source area 221 and the drain area 222 are arranged at both sides of the channel 223 correspondingly. Please refer to FIG. 4a.

In the present embodiment, the metallic oxide semiconductor layer 22 is patterned by means of development, wet-etching, dry-etching, etc., which is not specifically limited by the present disclosure.

At block S102, the gate insulating layer 23 is formed on the channel 223 of the metallic oxide semiconductor layer 22, and a gate 24 is formed on the gate insulating layer 23.

The gate insulating layer 23 is deposited on the substrate 20 with the method such as CVD. The gate insulating layer 23 is arranged on the metallic oxide semiconductor layer 22 and the substrate 20 where no metallic oxide semiconductor layer 22 is arranged. Further, a gate metallic layer is formed on the gate insulating layer 23 with the method such as sputtering. The material of the gate metallic layer includes, but is not limited to, gold, silver, copper, and iron.

The gate insulating layer 23 and the gate metallic layer are patterned through a mask to arrange the patterned gate insulating layer 23 and the gate metallic layer on the channel 223 of the metallic oxide semiconductor. The gate 24 is formed on the gate insulating layer 23, as FIG. 4b illustrates.

In another embodiment, the gate insulating layer 23 is patterned to arrange the patterned gate insulating layer 23 on the channel 223 of the metallic oxide semiconductor layer 22. Afterwards, the gate metallic layer is deposited on the substrate 20; the gate metallic layer is etched; the gate metallic layer on the gate insulating layer 23 is preserved to form the gate.

At block S103, the source area 221 and the drain area 222 of the metallic oxide semiconductor layer 22 are etched with the metallic etching solution.

The semi-finished product of the array substrate according to block S102 is processed with the metallic etching solution. The metallic etching solution is an acid solution. Some of the metallic elements in the metallic oxide semiconductor layer 22 can be etched with the metallic etching solution, and the other metallic elements in the metallic oxide semiconductor layer 22 cannot be etched with the metallic etching solution. The metallic etching solution touches the exposed drain area 222 and the exposed source area 221 on the metallic oxide semiconductor layer 22 to remove the removable metallic elements of the drain area 222 and the source area 221 on the metallic oxide semiconductor layer 22 with the metallic etching solution and to preserve the other unremovable metallic elements with the metallic etching solution to further transform the metallic oxide semiconductor layer 22 including the drain area 222 and the source area 221 into a conductor. At this time, the structure of TFT is what is illustrated in FIG. 4b. The difference is that the drain area 222 and the source area 221 on the metallic oxide semiconductor layer 22 are the metallic oxide conductors.

The PH value of the metallic etching solution is adjusted based on practical demands. The metallic etching solution in the present embodiment is the titration ammonia solution. The PH of the metallic etching solution ranges from 3.8 to 4.5.

The metallic etching solution can be chosen based on the property of the metallic etching solution in this embodiment. The metallic oxide semiconductor may be an IGZO semiconductor layer. The metallic etching solution which corresponds to the metallic oxide semiconductor may be a copper-etching solution. When the array substrate 20 is processed with the copper-etching solution, gallium elements in the source area and the drain area of the IGZO semiconductor layer are removed with the copper-etching solution while an indium element and a zinc element are preserved. Thereby, the source area and the drain area of the IGZO semiconductor layer are transformed into an oxide conductors of the indium element and the zinc element.

At block S104, the metallic etching solution is removed and a interlayer insulating layer 25, a source 261, a drain 262, a passivation layer 27, and a pixel electrode 28 are formed on the substrate 20 successively.

The array substrate, which has been processed with the metallic etching solution, is processed to remove the metallic etching solution on the array substrate 20. Afterwards, the interlayer insulating layer 25, the source 261, the drain 262, the passivation layer 27, and the pixel electrode 28 are successively deposited to form an entire TFT.

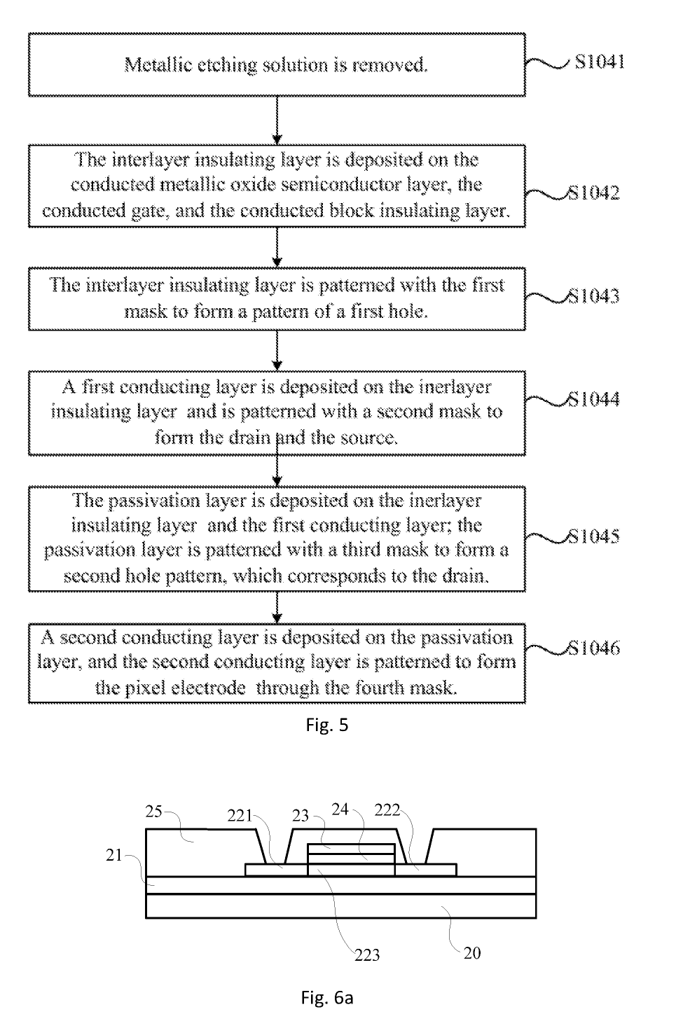

Further, please refer to FIG. 5. The block S104 may include block S1041, block S1042, block S1043, block S1044, block S1045, and block S1046.

At block S1041, the metallic etching solution is removed.

The array substrate, which has been processed with the metallic etching solution, undergoes pickling, and further the metallic etching solution is removed. To ensure that the metallic etching solution is totally removed from the array substrate, the array substrate undergoes pickling for a period of time; that is, the array substrate undergoes continuous pickling until the metallic etching solution is completely removed. In this embodiment, the continuous time for removing the metallic etching solution may range from 10 seconds to 20 seconds. In addition, the material of pickling the metallic etching solution is not specifically limited.

At block S1042, the interlayer insulating layer 25 is deposited on the conducted metallic oxide semiconductor layer 22, the conducted gate 24, and the conducted block insulating layer 21.

The interlayer insulating layer 25 is deposited on the substrate 20 with the method such as CVD. The interlayer insulating layer 25 covers the gate 24, the metallic oxide semiconductor layer 22, which has been processed with the metallic etching solution, and the block insulating layer 21 where no metallic oxide semiconductor layer 22 is arranged. Optionally, an upper surface of the interlayer insulating layer 25 away from the substrate 20 may be a flat surface.

At block S1043, the interlayer insulating layer 25 is patterned with the first mask to form a pattern of a first hole.

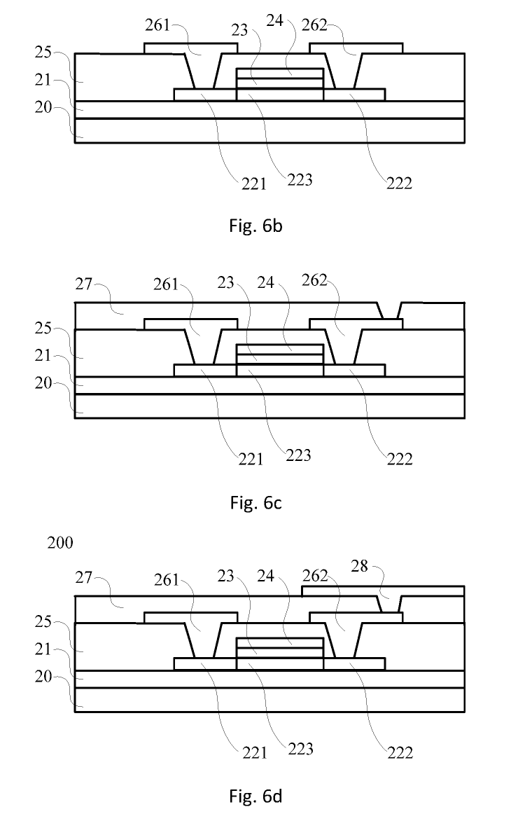

The interlayer insulating layer 25 is patterned with a mask; that is, the first hole is arranged on the interlayer insulating layer 25. The first hole is configured to connect the source 261 fabricated according to a subsequent block and the drain 262 fabricated according to a subsequent block to the metallic oxide semiconductor layer, which has been processed with the metallic etching solution. Therefore, the position of the first hole corresponds to the position of the drain area 222 and the position of the source area 221 of the metallic oxide semiconductor layer 22. The drain area 222 and source area 221 of the metallic oxide semiconductor layer 22 are partially exposed through the first hole. Please refer to FIG. 6a.

In the present embodiment, the inerlayer insulating layer 25 is patterned by means of development, wet-etching, dry-etching, etc., which is not specifically limited by the present disclosure.

At block S1044, a first conducting layer is deposited on the inerlayer insulating layer 25 and is patterned with a second mask to form the drain 262 and the source 261.

The first conducting layer is formed on the substrate 20 with the method such as sputtering and patterned with a mask so that the drain 262 and the source 261 are formed on the first conducting layer. The material of the gate metallic layer includes, but is not limited to, gold, silver, copper, and iron. The drain 262 corresponds to the drain area 222 of the metallic oxide semiconductor layer 22. The first hole formed according to block S1043 touches the metallic oxide semiconductor layer 22 at the drain area 222 partially. The source 261 corresponds to the source area 221 of the metallic oxide semiconductor layer 22. The first hole formed according to block S1043 touches the metallic oxide semiconductor layer 22 at the source area 221 partially. Please refer to FIG. 6b.

In the present embodiment, the first conducting layer is patterned by means of development, wet-etching, dry-etching, etc., which is not specifically limited by the present disclosure.

At block S1045, the passivation layer 27 is deposited on the inerlayer insulating layer 25 and the first conducting layer; the passivation layer 27 is patterned with a third mask to form a second hole pattern, which corresponds to the drain 262.

The passivation layer 27 is deposited on the substrate 20 with the method such as CVD. At this time, the passivation layer 27 covers the exposed inerlayer insulating layer 25, the drain 262 formed according to block S1044, and the source 261 formed according to block S1044. Further, the passivation layer 27 is patterned with a mask so as to form a second hole on the passivation layer 27. The second hole is configured to connect the pixel electrode 28 fabricated according to a subsequent block to the drain 262 fabricated according to a subsequent block. Therefore, the position of the second hole corresponds to the position of the drain 262 formed according to block S1044. The structure of the formed TFT 200 can be understood after reference to FIG. 6c.

In the present embodiment, the passivation layer 27 is patterned by means of development, wet-etching, dry-etching, etc., which is not specifically limited by the present disclosure.

At block S1046, a second conducting layer is deposited on the passivation layer 27; the second conducting layer is patterned to form the pixel electrode 28 through the fourth mask.

The second conducting layer is deposited on the passivation layer 27 with a method such as sputtering and CVD. The second conducting layer is patterned with a mask, and an area of the second conducting layer which corresponds to a pixel unit is preserved to form the pixel electrode 28. The second conducting layer is connected to the drain 262 through the second hole, which is fabricated in block S1045, as FIG. 6d illustrates. The second conducting layer is an indium tin oxide (ITO) conducting layer, and the pixel electrode 28, which the second conducting layer corresponds to, is the ITO pixel electrode 28 in the present embodiment.

In the present embodiment, the second conducting layer is patterned by means of development, wet-etching, dry-etching, etc., which is not specifically limited by the present disclosure.

According to the present disclosure, a metallic etching solution is adopted to process metallic oxide semiconductor. The metallic etching solution removes metallic elements which are inclined to be etched by the metallic etching solution, and the other metallic elements which are hard to be etched by the metallic etching solution are preserved. In other words, the metallic oxide semiconductor is transformed into a conductor. Since the metallic elements are removed from the metallic oxide semiconductor, an oxygen element in a silicon oxide at both sides of the metallic oxide semiconductor does not extend to the merely transformed conductor, thereby enhancing the stability of the metallic oxide conductor and the performance of the TFT.

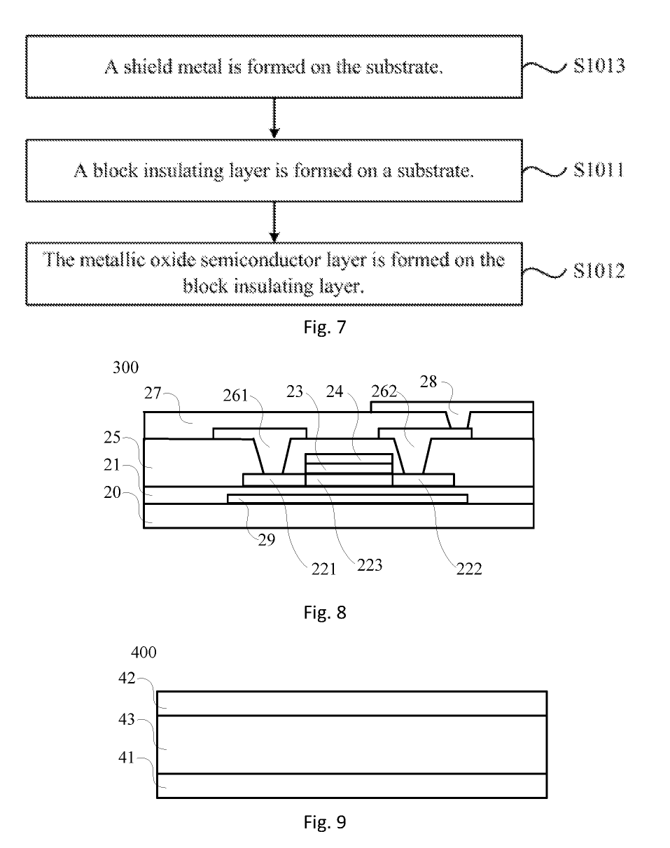

Further, before the block S1011 of the block S101, block S1013 may be included, as FIG. 7 illustrates.

At block S1013, a shield metal 29 is formed on the substrate 20.

A metallic layer is deposited on the substrate 20, and then the metallic layer is patterned to form the shield metal 29. Afterwards, block S102, block S103, and block S104 are conducted followed by block S1011 and block S1012. The structure of the TFT 300 is illustrated in FIG. 8.

Further, an array substrate is proposed by the present disclosure. The array substrate includes a substrate and a plurality of thin film transistors (TFTs). The plurality of TFTs are arranged on the substrate.

The present disclosure proposes an array substrate including a substrate and a plurality of thin film transistors (TFTs) arranged on the substrate. The TFT includes a block insulating layer arranged on the substrate and a metallic oxide semiconductor layer formed on the block insulating layer, The metallic oxide semiconductor layer includes a source area, a drain area, and a channel. The TFT also includes a gate insulating layer and a gate, both arranged on the channel of the metallic oxide semiconductor layer. The TFT also includes an interlayer insulating layer, a source, a drain, a passivation layer and a pixel electrode, all arranged on the metallic oxide semiconductor layer, the gate insulating layer, and the gate. The source is connected to the source area of the metallic oxide semiconductor layer. The drain is connected to the drain area of the metallic oxide semiconductor layer. The pixel electrode is connected to the drain. The source area and the drain area of the metallic oxide semiconductor layer are etched with a metallic etching solution.

The TFT on the array substrate proposed by the present embodiment can be fabricated with the fabrication method illustrated from FIG. 2 to FIG. 7 as well. The structure of the TFT is like what FIG. 6d or FIG. 8 illustrates and can be referred directly if needed. The structure of the TFT will not be detailed in this specification.

Further, a liquid crystal display (LCD) panel 400 is proposed in another embodiment of the present disclosure. As FIG. 9 illustrates, the LCD panel 400 includes an array substrate 41, a color film substrate 42, and a liquid crystal layer 43. The liquid crystal layer 43 is arranged between the array substrate 41 and the color film substrate 42. A plurality of thin film transistors (TFTs) are arranged on the array substrate 41. The plurality of TFTs can be fabricated with a fabrication method as illustrated from FIG. 3 to FIG. 7. The structure of the TFTs are like what FIG. 6d or FIG. 8 illustrates and can be referred directly if needed. The structure of the TFTs will not be detailed in this specification.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

1. A liquid crystal display panel, comprising an array substrate, a color filter substrate and a liquid crystal layer therebetween, wherein the array substrate comprises a substrate and a plurality of thin film transistors (TFTs) arranged on the substrate, the TFT comprising:
a block insulating layer, arranged on the substrate;
a metallic oxide semiconductor layer, formed on the block insulating layer and comprising a source area, a drain area, and a channel;
a gate insulating layer and a gate, arranged on the channel of the metallic oxide semiconductor layer;
an interlayer insulating layer, a source, a drain, a passivation layer and a pixel electrode, arranged on the metallic oxide semiconductor layer, the gate insulating layer, and the gate; the source being connected to the source area of the metallic oxide semiconductor layer; the drain being connected to the drain area of the metallic oxide semiconductor layer; the pixel electrode being connected to the drain,
wherein the source area and the drain area of the metallic oxide semiconductor layer are etched with a metallic etching solution,
wherein a shield metal is arranged between the substrate and the block insulating layer,
wherein the metallic oxide semiconductor layer is an indium gallium zinc oxide (IGZO) semiconductor layer; the metallic etching solution is a copper-etching solution.

2. The liquid crystal display panel of claim 1, wherein the PH value of the metallic etching solution ranges from 3.8 to 4.5.

3. The liquid crystal display panel of claim 1, wherein the metallic oxide semiconductor layer is an indium gallium zinc oxide (IGZO) semiconductor layer, and the metallic etching solution is a copper-etching solution.

4. The liquid crystal display panel of claim 3, wherein the source area and the drain area of the IGZO semiconductor layer are etched with the copper-etching solution, and an indium element and a zinc element are preserved.

5. An array substrate, comprising a substrate and a plurality of thin film transistors (TFTs) arranged on the substrate, the TFT comprising:
a block insulating layer, arranged on the substrate;
a metallic oxide semiconductor layer, formed on the block insulating layer and comprising a source area, a drain area, and a channel;
a gate insulating layer and a gate, arranged on the channel of the metallic oxide semiconductor layer;
an interlayer insulating layer, a source, a drain, a passivation layer and a pixel electrode, arranged on the metallic oxide semiconductor layer, the gate insulating layer, and the gate; the source being connected to the source area of the metallic oxide semiconductor layer; the drain being connected to the drain area of the metallic oxide semiconductor layer; the pixel electrode being connected to the drain,
wherein the source area and the drain area of the metallic oxide semiconductor layer are etched with a metallic etching solution.

6. The array substrate of claim 5, wherein a shield metal is arranged between the substrate and the block insulating layer.

7. The array substrate of claim 5, wherein the PH value of the metallic etching solution ranges from 3.8 to 4.5.

8. The array substrate of claim 5, wherein the metallic oxide semiconductor layer is an indium gallium zinc oxide (IGZO) semiconductor layer; the metallic etching solution is a copper-etching solution.

9. The array substrate of claim 8, wherein the source area and the drain area of the IGZO semiconductor layer are etched with the copper-etching solution, and an indium element and a zinc element are preserved.

10. A fabrication method of a thin film transistor (TFT), comprising:
forming a metallic oxide semiconductor layer on a substrate; the metallic oxide semiconductor layer comprises a source area, a drain area, and a channel;
forming a gate insulating layer on the channel of the metallic oxide semiconductor layer, and forming a gate on the gate insulating layer;
etching the source area and the drain area of the metallic oxide semiconductor layer with a metallic etching solution to transform the metallic oxide semiconductor layer at the source area and the drain area into a conductor; and
removing the metallic etching solution, and continuously depositing an interlayer insulating layer, a source, a drain, a passivation layer, and a pixel electrode successively.

11. The fabrication method of claim 10, wherein the PH value of the metallic etching solution ranges from 3.8 to 4.5.

12. The fabrication method of claim 10, wherein the metallic oxide semiconductor layer is an indium gallium zinc oxide (IGZO) semiconductor layer; the metallic etching solution is a copper-etching solution,
wherein the source area and the drain area of the metallic oxide semiconductor layer is etched with the metallic etching solution;
the source area and the drain area of the IGZO semiconductor layer are etched with the copper-etching solution, and an indium element and a zinc element are preserved.

13. The fabrication method of claim 10, wherein the removing of the metallic etching solution comprising:
pickling the substrate, the metallic oxide semiconductor layer, the gate insulating layer, and the gate to remove the metallic etching solution.

14. The fabrication method of claim 10, wherein before the forming of the metallic oxide semiconductor layer on the substrate, the fabrication method comprises:
forming a shield metal on the substrate;
the forming of the metallic oxide semiconductor layer on the substrate comprising:
depositing a block insulating layer on the shield metal and the substrate where the shield metal is not formed;
forming the metallic oxide semiconductor layer on the block insulating layer.

15. The fabrication method of claim 10, wherein the depositing of the interlayer insulating layer, the source, the drain, the passivation layer, and the pixel electrode successively comprising:
depositing the interlayer insulating layer on the conducted metallic oxide semiconductor layer, the conducted gate, and a conducted block insulating layer;
patterning the interlayer insulating layer with a first mask to form a pattern of a first hole; corresponding the pattern of the first hole to the drain area and the source area of the metallic oxide semiconductor layer;
depositing a first conducting layer on the inerlayer insulating layer and patterning the first conducting layer with a second mask to form the drain and the source; corresponding the drain and the source to the drain area and the source area of the metallic oxide semiconductor layer respectively;
depositing the passivation layer on the inerlayer insulating layer and the first conducting layer; patterning the passivation layer with a third mask to form a pattern of a second hole; corresponding the pattern of the second hole to the drain;
depositing a second conducting layer; patterning the second conducting layer with a fourth mask to form the pixel electrode.
